(19) United States
(12) Patent Application Publication
(10) Pub. No.: US 2003/0117208 A1
(43) Pub. Date: Jun. 26, 2003

(54) InSb signal-conditioning circuit with built-in temperature compensation

(76) Inventor: Robert E. Bicking, Freeport, IL (US)

Correspondence Address: HONEYWELL INTERNATIONAL INC., 101 COLUMBIA ROAD, P O BOX 2245, MORRISTOWN, NJ, 07962-2245, US

(21) Appl. No.: 10/026,270

(22) Filed: Dec. 21, 2001

(51) Int. Cl. H03K 3/42

(52) U.S. Cl. 327/513

(57) ABSTRACT

A method and system for signal-conditioning utilizing a signal-conditioning circuit is disclosed. An offset correction voltage can be applied to a noninverting input of a signal-conditioning circuit. A magnetoresistor half-bridge signal can be applied to an inverting input of the signal-conditioning circuit. A voltage can then be compensated at the noninverting input to drive an output voltage of the signal-conditioning circuit to an input voltage divided by a value of two by calibration, thereby permitting the signal-conditioning circuit to contain temperature compensation capabilities.

### TECHNICAL FIELD

The present invention is generally related to signal-conditioning methods and systems. The present invention is also related to magnetoresistors utilized in signal-conditioning circuits. The present invention is additionally related to temperature compensation techniques and devices thereof. The present invention is also additionally related to InSb magnetoresistors and back-biased magnetic sensors thereof.

### BACKGROUND OF THE INVENTION

Magnetic sensing devices for detecting the presence of a ferromagnetic object in the vicinity of the sensing device are widely used in a variety of fields, including automotive applications. Such sensing devices typically utilize a magnetic field and employ sensing apparatus that detect changes in the strength of a magnetic field. Magnetic field strength can be defined generally as the magnetomotive force developed by a permanent magnet per the distance in the magnetization direction. As an example, an increase in the strength of a magnetic field, corresponding to a drop in the reluctance of a magnetic circuit, will occur as an object made from a high magnetic permeability material, such as iron, is moved toward the magnet.

Magnetic permeability is the ease with which the magnetic lines of force, designated as magnetic flux, can pass through a substance magnetized with a given magnetizing force. Quantitatively, it can be expressed as the ratio between the magnetic flux density (the number or lines of magnetic flux per unit area which are perpendicular to the direction of the flux) produced and the magnetic field strength, or magnetizing force. Because the output signal of a magnetic field sensing device is dependent upon the strength of the magnetic field, it is generally effective in detecting the distance between the sensing device and an object within the magnetic circuit. The range within which the object can be detected is limited by the flux density, as measured in Gauss or Teslas.

Where it is desired to determine the speed or rotational position of a rotating object, such as a disk mounted on a shaft, the object is typically provided with surface features that project toward the sensing device, such as teeth. The proximity of a tooth to the sensing device will increase the strength of the magnetic field. Accordingly, by monitoring the output of the sensing device, the rotational speed of the disk can be determined by correlating the peaks in the sensor's output with the known number of teeth on the circumference of the disk. Likewise, when the teeth are irregularly spaced in a predetermined pattern, the rotational position of the body can be determined by correlating the peak intervals with the known intervals between the teeth on the disk.

One prominent form of such a sensing device is a Hall effect sensor. A Hall effect sensor relies upon a transverse current flow that occurs in the presence of a magnetic field. The Hall effect sensor is primarily driven by a direct current voltage source having electrodes at both ends of the Hall effect sensor, creating a longitudinal current flow through the sensor's body. In the presence of a magnetic field, a transverse current is induced in the sensor, which can be detected by a second pair of electrodes transverse to the first pair. The second pair of electrodes can then be connected to a voltmeter to determine the potential created across the surface of the sensor. This transverse current flow increases with a corresponding increase in the magnetic field's strength.

Generally, the Hall effect sensor is mounted within and perpendicular to a magnetic circuit, which includes a permanent magnet and an exciter. The exciter is a high magnetic permeability element having projecting surface features, which increase the strength of the magnet's magnetic field as the distance between the surface of the exciter and the permanent magnet is reduced. Typically, the exciter will be in the form of a series of spaced teeth separated by slots, such as the teeth on a gear. The exciter moves relative to the stationary Hall effect sensor element, and in doing so, changes the reluctance of the magnetic circuit so as to cause the magnetic flux through the Hall effect element to vary in a manner corresponding to the position of the teeth. With the change in magnet flux there occurs the corresponding change in magnet field strength, which increases the transverse current of the Hall effect sensor.

With the increasing sophistication of products, magnetic field sensing devices have also become common in products that rely on electronics in their operation, such as automobile control systems. Common examples of automotive applications are the detection of ignition timing from the engine crankshaft and/or camshaft and the detection of wheel speed for anti-lock braking systems and four-wheel steering systems. For detecting wheel speed, the exciter is typically an exciter wheel mounted inboard from the vehicle's wheel, the exciter wheel being mechanically connected to the wheel so as to rotate with the wheel.

The exciter wheel is provided with a number of teeth, which typically extend axially from the perimeter of the exciter wheel to an inboard-mounted magnetic field sensor. As noted before, the exciter wheel is formed of a high magnetic permeability material, such as iron, such that as each tooth rotates toward the sensor device, the strength of the magnetic field increases as a result of a decrease in the magnetic circuit's reluctance. Subsequently, the magnetic circuit reluctance increases and the strength of the magnetic field decreases as the tooth moves away from the sensing device. In the situation where a Hall effect device is used, there will be a corresponding peak in the device's potential across the transverse electrodes as each tooth passes near the device.

One type of magnetic sensing device utilized in automotive applications, in particular, is a magnetoresistor. A magnetoresistor is a device whose resistance varies with the strength of the magnetic field applied to the device. Generally, the magnetoresistor is a slab of electrically conductive material, such as a metal or a semiconductor. For many automotive applications, the preferred form of a magnetoresistor is generally a thin elongated body of a high carrier mobility semiconductor material, such as indium antimonide (InSb) having contacts at its ends. Such a device operates on the same principle (deflection of charge carriers by a magnetic field) as a Hall element. InSb has the highest mobility (μ) of any semiconductor material, and the sensitivity is proportional to μ² when biased at 2000 to 3000 gauss. Such a magnetoresistor can be mounted within and perpendicular to a magnetic circuit, which can include a permanent magnet and an exciter. The exciter moves relative to the stationary magnetoresistor element and, in doing so, changes the reluctance of the magnetic circuit so as to cause the magnetic flux through the magnetoresistor element to vary in a manner corresponding to the position of the teeth of the exciter. With the change in magnetic flux there occurs the corresponding change in magnet field strength, which increases the resistance of the magnetoresistor.

Generally, back-biased magnetic sensors that utilize InSb magnetoresistors and permanent magnets do exhibit a negative scale factor temperature coefficient. If two magnetoresistors are perfectly matched and connected in a voltage divider configuration, no resultant scale factor shift with temperature would result. There will invariably be a mismatch, however, which is an unavoidable result of the integrated circuit manufacturing process. The deposition of this very high mobility semiconductor material on a substrate (usually, a GaAs wafer) involves gradients in doping level, thickness, etc., which results in the two magnetoresistors having slightly different resistance values and slightly different temperature coefficients, even between two adjacent magnetoresistors on the substrate. A scale factor, which does not change with temperature, is desired. To date, a reliable method and system, including circuit implementations thereof, for temperature compensation in magnetoresistor-based sensors, has not been achieved. The present inventor has concluded, based on the foregoing, that a need exists for a signal-conditioning circuit that can achieve built-in temperature compensation. The present inventor has also concluded, based on the foregoing, that such a signal-conditioning circuit is particularly preferred in back-biased magnetic sensor devices, which utilize InSb magnetoresistors. The present invention thus meets this important need, as further described herein.

### BRIEF SUMMARY OF THE INVENTION

The following summary of the invention is provided to facilitate an understanding of some of the innovative features unique to the present invention and is not intended to be a full description. A full appreciation of the various aspects of the invention can be gained by taking the entire specification, claims, drawings, and abstract as a whole.

It is, therefore, one aspect of the present invention to provide an improved signal-conditioning circuit.

It is another aspect of the present invention to provide a signal-conditioning circuit with built-in temperature compensation capabilities.

It is yet another aspect of the present invention to provide an InSb signal-conditioning circuit which utilizes InSb magnetoresistors.

The above and other aspects of the invention can be achieved as is now described. A method and system for signal-conditioning utilizing a signal-conditioning circuit is disclosed herein. In automotive and other applications, for example, the operation of the electronics from a single supply is desirable for cost and simplicity. This means that the circuit is required to operate around Vₛ/2, where Vₛ is the supply voltage, to maximize the useful dynamic range of the circuit. This requires a voltage bias to obtain Vₛ/2. This bias voltage can be applied to a noninverting input of a signal-conditioning circuit. A magnetoresistor half-bridge signal can be applied to an inverting input of the signal-conditioning circuit. The signal-conditioning circuit itself can be configured to comprise an InSb signal-conditioning circuit, which is based on InSb magnetoresistors. The signal-conditioning circuit can generally be configured as a circuit which includes a noninverting signal input for application of offset correction voltages, an inverting input for application of magnetoresistor half bridge signals, and a temperature compensator. It is important to note that if only one magnetoresistor is utilized, a very large negative temperature coefficient will result. If two magnetoresistors are utilized in a voltage divider as explained earlier, only a residual temperature coefficient results. The magnet has its own negative temperature coefficient, which adds to that of the magnetoresistors.

The magnetoresistor half-bridge signal can be generated utilizing one or more magnetoresistors configured within the signal-conditioning circuit. The signal-conditioning circuit can include at least two magnetoresistors. Thus, the signal-conditioning circuit can be configured to include a first magnetoresistor coupled to a second magnetoresistor at a first node, wherein the first magnetoresistor is coupled to a supply voltage and the second magnetoresistor is coupled to a ground. Additionally, the signal-conditioning circuit can include a first resistor coupled to a second resistor at a second node, wherein the first resistor is coupled to the supply voltage and the second resistor is coupled to the ground, such that the second node is coupled to a positive input of the amplifier. Also, the signal-conditioning circuit can include a third resistor coupled to the first node and to a third node, wherein the third node is connected to a negative input of the amplifier. The signal-conditioning circuit additionally can include a fourth resistor coupled to the third node and to an output of the amplifier.

The signal-conditioning circuit generally can be configured to comprise at least one magnetoresistor in series with at least one resistor located in an inverting input of an amplifier associated with the signal-conditioning circuit, wherein such a magnetoresistor exhibits a negative scale factor temperature coefficient. An associated magnet can thus exhibit a negative scale factor temperature coefficient to thereby permit a gain of the amplifier to increase with temperature. The signal-conditioning circuit can additionally include at least one resistor, which comprises a fixed low temperature coefficient resistor. Such a fixed low temperature coefficient resistor can be chosen to thereby obtain a nearly flat resultant scale factor temperature coefficient thereof.

Thus, InSb magnetoresistors exhibit a negative temperature coefficient that can be used to compensate for the magnetoresistor (MR) scale factor shift and the magnet scale factor shift in a back-based sensor. The signal-conditioning circuit described herein places the magnetoresistors in series with a fixed low temperature coefficient (TC) resistor in the inverting input of an amplifier. Because the magnetoresistors exhibit a negative scale factor temperature coefficient and the magnet exhibits a negative scale factor temperature coefficient, the gain of the amplifier increases with the temperature. By proper choice of the fixed resistor in series with the magnetoresistors, a nearly flat resultant scale factor temperature coefficient can thus be obtained.

### BRIEF DESCRIPTION OF THE DRAWINGS

The accompanying figures, in which like reference numerals refer to identical or functionally-similar elements throughout the separate views and which are incorporated in and form part of the specification, further illustrate the present invention and, together with the detailed description of the invention, serve to explain the principles of the present invention.

FIG. 1 illustrates an analog output signal-conditioning circuit with magnetoresistors, in accordance with a preferred embodiment of the present invention;

FIG. 2 depicts a signal-conditioning circuit with a digital output that may be implemented in accordance with a preferred embodiment of the present invention;

FIG. 3 depicts a technique for calculating an equivalent circuit utilizing Thevenin's theorem, in accordance with a preferred embodiment of the present invention;

FIG. 4 illustrates an equivalent circuit, in accordance with a preferred embodiment of the present invention; and

FIG. 5 depicts a temperature coefficient graph for InSb magnetoresistors.

### DETAILED DESCRIPTION OF THE INVENTION

The particular values and configurations discussed in these non-limiting examples can be varied and are cited merely to illustrate an embodiment of the present invention and are not intended to limit the scope of the invention.

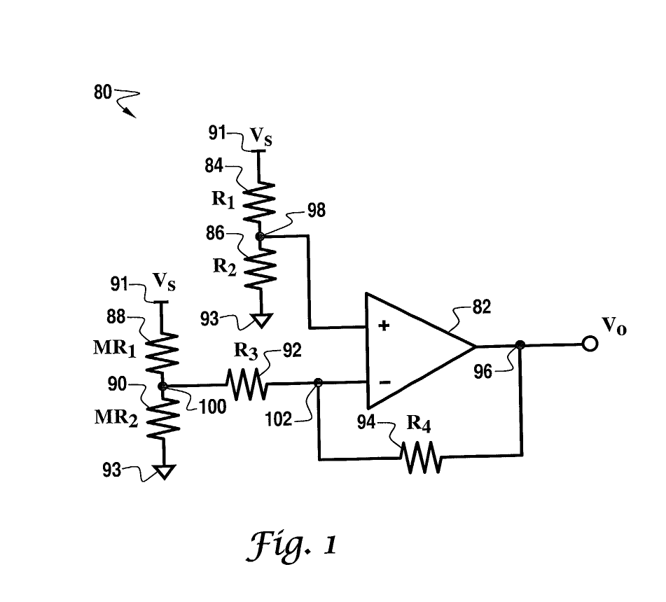

FIG. 1 illustrates a signal-conditioning circuit 80 with magnetoresistors, in accordance with a preferred embodiment of the present invention. Note that in FIGS. 1-4 illustrated herein, like parts are generally indicated by identical reference numerals. Signal-conditioning circuit 80 can generate a magnetoresistor half-bridge signal utilizing one or more magnetoresistors 88 and 90. Thus, signal-conditioning circuit 80 includes a first magnetoresistor 88 coupled to a second magnetoresistor 90 at a first node 100. First magnetoresistor 88 is coupled to a supply voltage 91. Second magnetoresistor 90 is coupled to a ground 93. Signal-conditioning circuit 80 additionally includes a first resistor 84 coupled to a second resistor 86 at a second node 98. The first resistor 84 is coupled to supply voltage 91, and the second resistor 86 is coupled to ground 93. The second node 98 is coupled to a positive input of amplifier 82. Signal-conditioning circuit 80 also includes a third resistor 92 coupled to first node 100 and to a third node 102, wherein third node 102 is connected to a negative input of amplifier 82. The signal-conditioning circuit additionally includes a fourth resistor 94 coupled to third node 102 and to an output of amplifier 82 at a node 96, which also produced an output voltage Vₒ. Circuit 80 of FIG. 1 thus can produce an analog output voltage for ferrous target movement with respect to the sensor.

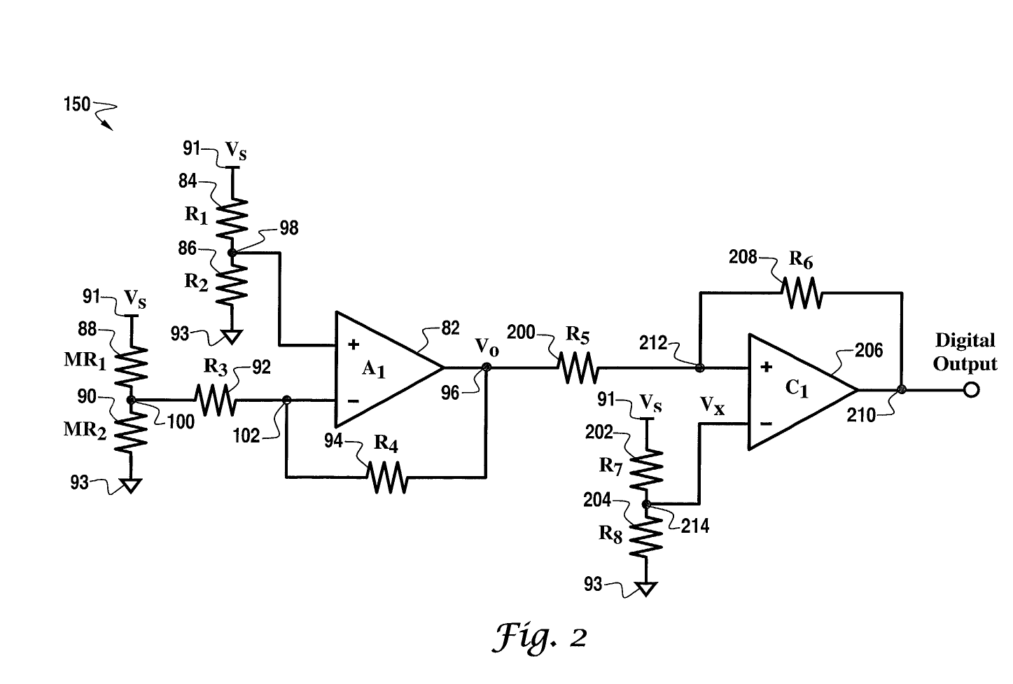

FIG. 2 depicts a circuit 150, which adds a comparator 206 to the basic circuit 80 illustrated in FIG. 1 to provide a digital output 210, suitable for direct interface with an engine controller in an automotive gear tooth sensing application. In FIGS. 1-2, like parts are indicated by identical reference numerals. Circuit 150 of FIG. 2 thus includes the same circuit elements illustrated in FIG. 1. Circuit 150 also includes a resistor 200, which is connected to an output 96 of amplifier 82. Resistor 200 is labeled R₅ and is connected to a resistor 208, which is labeled R₆ at a node 212. A positive input of comparator 206 is also connected to node 212. A resistor 202, which is labeled R₇, is connected to supply voltage 91 and a node 214, which in turn is connected to a negative input of comparator 206 and a resistor 204. The resistor 204 is labeled R₈ and node 214 is labeled Vₓ. Resistor 204 is generally connected between ground 93 and node 214. Resistor 208 is connected to node 212 and node 210. Node 210 constitutes a digital output.

Generally, when Vₒ>Vₓ, the digital output (i.e., node 210) is equal to Vₛ. When Vₒ is less than or equal to Vₓ, the digital output (i.e., node 210) is equivalent to 0 volts. Thus, the analog output from amplifier 82 (i.e., A₁) is fed to a non-inverting input of comparator 206 (i.e., C₁) through resistor 200. Note that comparator 206 can be configured as, for example, a comparator integrated circuit (IC) or a high-speed amplifier IC. Resistor 208 (i.e., R₆) provides hysteresis to the comparator 206 to ensure fast switching capabilities. The amount of hysteresis can be provided by the following formulation: δV=(Vₛ·R₅)/2(R₅+R₆)=2.5 mv for Vₛ=5 v, R₅=10 k, R₆=10 meg. R₇ and R₈ provide a reference voltage (i.e., Vₓ) to comparator 206. Note that Vₓ=2.5v for R₇=R₈=5k. Although FIG. 2 is not discussed in further detail, circuit 150 has been included to illustrate that the present invention can apply to both analog and digital output signal-conditioning circuits.

For illustrative purposes only, it is assumed that the following values are utilized in FIGS. 1-2:

R1=5 kΩ

R2=4 kΩ trimmable chip resistor

R3=500Ω trimmable chip resistor

R4=10 kΩ trimmable chip resistor

MR1≈MR2=800Ω at B=2500 gauss

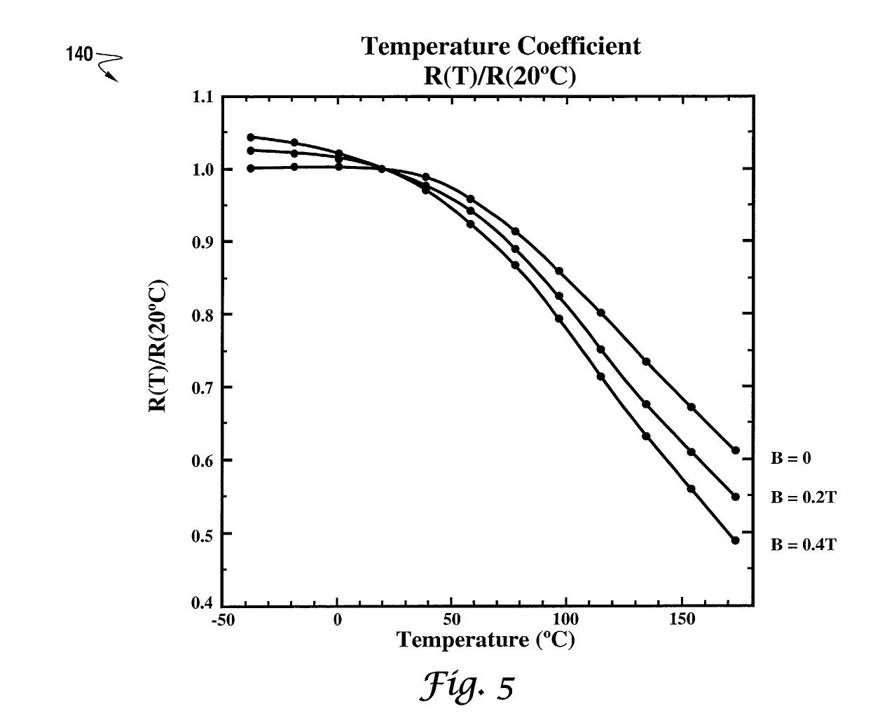

Generally, the negative TC_{R} of one or more magnetoresistor (MR) can be utilized to compensate the negative TC of magnet field strength by causing the gain of the amplifier to increase with temperature. Proper choice of R₆ can achieve this. Scale factor compensation is needed over the exemplary operating temperature range of −10° C. to 50° C. The TC_{R} is illustrated in FIG. 5 and is approximately −0.71Ω/° C. over the aforementioned temperature range. If a SmCo magnet is utilized, for example, preferably for high energy and excellent stability over time and temperature, the magnet TC_{B} is −0.03%/° C. Note that FIG. 5 generally depicts a temperature coefficient graph 140 for InSb magnetoresistors. Graph 140 illustrates a graph of R(T)/R(20° C.) versus Temperature (20° C.). InSb magnetoresistors are usually biased between 2000 and 3000 gauss (0.2T and 0.3T) where the sensitivity is a maximum. This graph may be used to determine the amount of resistance change over the operating temperature range.

Circuit 80 applies an offset correction voltage to the noninverting input and the MR half bridge signal to the inverting input. Due to mismatch of the two magnetoresistors and magnet mispositioning, V_{P2}≠Vₛ/2. Therefore, the voltage at the noninverting input compensate this value to drive Vₒ=Vₛ/2 by calibration.

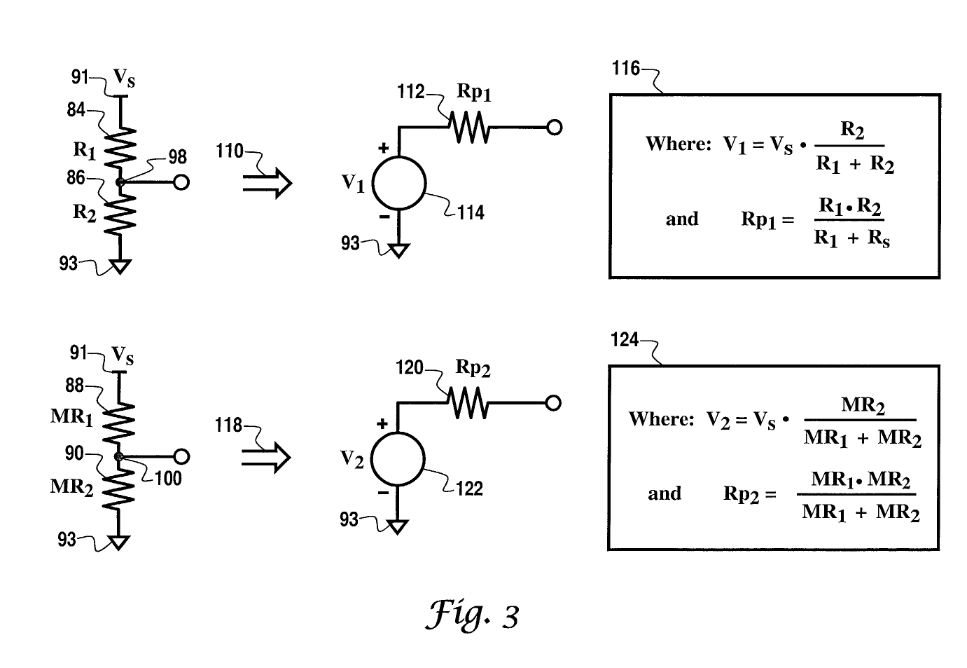

FIG. 3 depicts a technique for calculating a Thevenin equivalent circuit, in accordance with a preferred embodiment of the present invention. Thus, as indicated by arrow 110 in FIG. 3, resistors 84 and 86 can be arranged as an equivalent circuit composed of an equivalent resistor 112 and an equivalent voltage 114. Resistor 112 and voltage 114 are respectively labeled R_{P1} and V₁ in FIG. 3, where the following voltage and resistance are calculated:

$$\begin{matrix}{V}_{1} = {V}_{s} \times \frac{{R}_{2}}{{R}_{1} + {R}_{2}} \\ {R}_{P1} = \frac{{R}_{1} \times {R}_{2}}{{R}_{1} + {R}_{s}}\end{matrix} \qquad ( 4 )$$

As illustrated by arrow 118 in FIG. 3, magnetoresistors 88 and 90 can be arranged as a Thevenin equivalent circuit composed of an equivalent magnetoresistor 120 and equivalent voltage 122. Magnetoresistor 120 and voltage 122 are respectively labeled R_{P2} and V₂ in FIG. 3, where the following voltage and resistance can be calculated:

$$\begin{matrix}{V}_{2} = {V}_{s} \times \frac{MR2}{MR1 + MR2} \\ {R}_{P2} = \frac{MR1 \times MR2}{MR1 + MR2}\end{matrix} \qquad ( 5 )$$

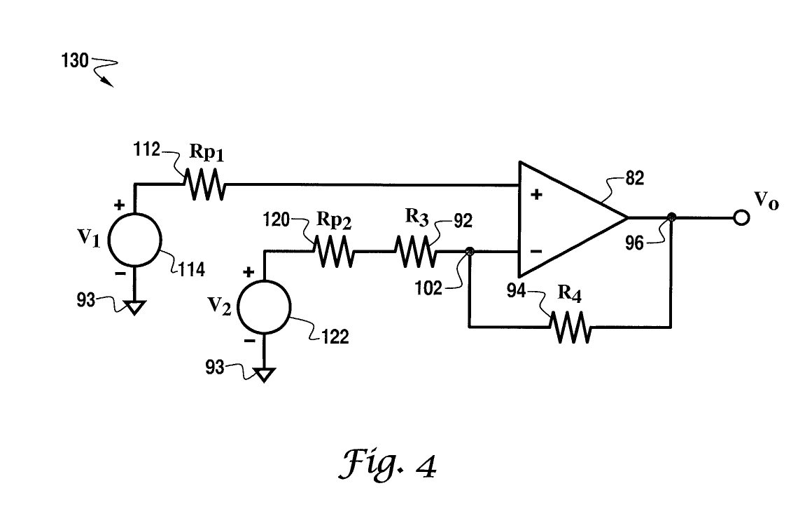

FIG. 4 illustrates an equivalent circuit 130, in accordance with a preferred embodiment of the present invention. Equivalent circuit 130 is analogous to circuit 80 of FIG. 1. As indicated above, in FIGS. 1-4 herein, like parts are indicated by identical reference numerals. Thus, equivalent circuit 130 includes amplifier 82 whose positive input is coupled to equivalent resistor 112, which in turn is connected to equivalent voltage 114. Amplifier 82 also includes a negative input coupled at node 102 to resistor 92, which in turn is coupled to equivalent magnetoresistor 120. Voltage 122 is connected to ground 93 and to equivalent magnetoresistor 120. Additionally, resistor 94 (i.e. R₄) is connected to node 102 and to node 96.

Thus, according to FIGS. 2, 3, and 4, the following mathematical formulations can be calculated:

Vₒ=V₁(G+1)−V₂G (6)

where:

$$G = \frac{{R}_{4}}{{R}_{P2} + {R}_{3}} \qquad ( 7 )$$

From equation 6, since the calibration procedure described later forces V₁≈V₂=Vₛ/2 with no ferrous target present, the offset depends only on V₁. From equation 7, the principle of built-in temperature compensation is evident: Since R_{P2} decreases as T (i.e., temperature) increases, G increases as temperature increases, thereby compensating the scale factor of the magnet and the scale factor of the magnetoresistors. This obviates the need for additional components to provide temperature compensation and also eliminates temperature-tracking errors, which may occur when external temperature compensation components are used. The value of R₃ required to provide compensation over the exemplary range of −10 to 50° C. may be found as follows.

$$\begin{matrix}G ( 10 ° ) = \frac{{R}_{4}}{{R}_{P2} ( 10 ° ) + {R}_{3}} ; & ( 8 ) \\ G ( 50 ° ) = \frac{{R}_{4}}{{R}_{P2} ( 50 ° ) + {R}_{3}} & ( 9 )\end{matrix}$$

G(50°)/G(10°)=[R_{P2}(10°)+R₃]/[R_{P2}(50°)+R₃] (10)

The gain ratio of equation 10 compensates the sensitivity decrease: δS=1−(60°·0.03%/° C.)=0.982. Refer to FIG. 5 herein to determine the values of the magnetoresistors: R_{P2} (10°)=400·1.02=408Ω; R_{P2} (50°)=400·0.96=384Ω.

Solving equation 10 for R₃ provides the following result: R₃=[δS·R_{P2} (10°)−R_{P2} (50°)]/[1−δS]. Thus, utilizing the component values provided above, R₃=922Ω.

Calibration can be performed according a specified series of steps. An example of a calibration sequence is provided below:

1. Measure R_{P2}. Using equation 10, laser trim R3 to the desired value.

2. Vₛ is adjusted according to the following: Vₛ=5.000±0.005 v.

3. The output of the magnetoresistors can be measured with no magnet present. The magnet can then be placed in the insert and moved until V (magnet)≈V (no magnet). A high temperature adhesive, such as superglue, may be utilized to hold the magnet in place. The insert is then installed in the housing and high temperature adhesive utilized to hold the insert in place.

4. Thereafter, with no target, R₂ (i.e., resistor 86 of FIG. 2) can be adjusted with a laser trimmer for Vₒ=2.500±0.002 v.

5. Thereafter, the target may be placed in front of the sensor, with the air gap between the target and the sensor set to the nominal value and the Y position of the target can be adjusted to obtain the same Vₒ as determined above.

6. The target is then displaced so that a target tooth is centered on one of the magnetoresistors. Then, R4 may be laser trimmed to set the gain to the desired value.

Based on the foregoing, it can be appreciated that the present invention generally discloses a method and system for signal-conditioning utilizing a signal-conditioning circuit. The present invention discloses a signal-conditioning circuit, including associated methods and systems thereof, which results in a scale factor that does not change with temperature. According to a preferred embodiment of the present invention, an offset correction voltage can be applied to a noninverting input of a signal-conditioning circuit. A magnetoresistor half-bridge signal can be applied to an inverting input of the signal-conditioning circuit. A voltage can then be compensated at the noninverting input to drive an output voltage of the signal-conditioning circuit to an input voltage divided by a value of two by calibration, thereby permitting the signal-conditioning circuit to contain temperature compensation capabilities. The signal-conditioning circuit itself can be configured to comprise an InSb signal-conditioning circuit, which is based on InSb magnetoresistors. The signal-conditioning circuit can generally be configured as a circuit which includes a noninverting signal input for application of offset correction voltages, an inverting input for application of magnetoresistor half bridge signals, and a temperature compensator.

The signal-conditioning circuit generally can be configured to comprise at least one magnetoresistor in series with at least one resistor located in an inverting input of an amplifier associated with the signal-conditioning circuit, wherein such a magnetoresistor exhibits a negative scale factor temperature coefficient. An associated magnet can thus exhibit a negative scale factor temperature coefficient to thereby permit a gain of the amplifier to increase with temperature. The signal-conditioning circuit can additionally include at least one resistor, which comprises a fixed low temperature coefficient resistor. Such a fixed low temperature coefficient resistor can be chosen to thereby obtain a flat resultant scale factor temperature coefficient thereof.

Thus, InSb magnetoresistors exhibit a negative temperature coefficient that can be used to compensate for the magnetoresistor (MR) scale factor shift and the magnet scale factor shift in a back-based sensor. The signal-conditioning circuit described herein places the magnetoresistors in series with a fixed low temperature coefficient (TC) resistor in the inverting input of an amplifier. Because the magnetoresistors exhibit a negative scale factor temperature coefficient and the magnet exhibits a negative scale factor temperature coefficient, the gain of the amplifier increases with the temperature. By proper choice of the fixed resistor and the magnetoresistors, a nearly flat resultant scale factor temperature coefficient can thus be obtained.

The embodiments and examples set forth herein are presented to best explain the present invention and its practical application and to thereby enable those skilled in the art to make and utilize the invention. Those skilled in the art, however, will recognize that the foregoing description and examples have been presented for the purpose of illustration and example only. Other variations and modifications of the present invention will be apparent to those of skill in the art, and it is the intent of the appended claims that such variations and modifications be covered. The description as set forth is not intended to be exhaustive nor to limit the scope of the invention. Many modifications and variations are possible in light of the above teaching without departing from the spirit and scope of the following claims. It is contemplated that the use of the present invention can involve components having different characteristics. It is intended that the scope of the present invention be defined by the claims appended hereto, giving full cognizance to equivalents in all respects.

The embodiments of the invention in which an exclusive property or right is claimed are defined as follows. Having thus described the invention what is claimed is:

1. A method for signal-conditioning utilizing a signal-conditioning circuit, said method comprising the step of:
applying an offset correction voltage to a noninverting input of a signal-conditioning circuit;
applying a magnetoresistor half-bridge signal to an inverting input of said signal-conditioning circuit;
compensating a voltage at said noninverting input to drive an output voltage of said signal-conditioning circuit to an input voltage divided by a value of two by calibration, thereby permitting said signal-conditioning circuit to contain temperature compensation capabilities.

2. The method of claim 1 further comprising the step of:
configuring said signal-conditioning circuit to comprise an InSb signal-conditioning circuit.

3. The method of claim 1 further comprising the step of:
configuring said signal-conditioning circuit as a circuit comprising:
a noninverting signal input for application of offset correction voltages;
an inverting input for application of magnetoresistor half bridge signals; and
a temperature compensator.

4. The method of claim 1 further comprising the step of:
generating said magnetoresistor half-bridge signal utilizing at least one equivalent magnetoresistor configured within said signal-conditioning circuit.

5. The method of claim 1 further comprising the step of:
generating said magnetoresistor half-bridge signal utilizing a plurality of magnetoresistors configured within said signal-conditioning circuit.

6. The method of claim 1 further comprising the step of:
configuring said signal-conditioning circuit to comprise at least two magnetoresistors.

7. The method of claim 1 further comprising the step of:
configuring said signal-conditioning circuit to comprise a first magnetoresistor coupled to a second magnetoresistor at a first node, wherein said first magnetoresistor is coupled to a supply voltage and said second magnetoresistor is coupled to a ground.

8. The method of claim 7 further comprising the step of:
configuring said signal-conditioning circuit to comprise a first resistor coupled to a second resistor at a second node, wherein said first resistor is coupled to said supply voltage and said second resistor is coupled to said ground, such that said second node is coupled to a positive input of said amplifier.

9. The method of claim 8 further comprising the step of:
configuring said signal-conditioning circuit to comprise a third resistor coupled to said first node and to a third node, wherein said third node is connected to a negative input of said amplifier.

10. The method of claim 9 further comprising the step of:
configuring said signal-conditioning circuit to comprise a fourth resistor coupled to said third node and to an output of said amplifier.

11. The method of claim 1 further comprising the step of:
configuring said signal-conditioning circuit to comprise at least one magnetoresistor in series with at least one resistor located in an inverting input of an amplifier associated with said signal-conditioning circuit;
wherein said at least one magnetoresistor comprises an InSb magnetoresistor that exhibits a negative scale factor temperature coefficient; and
wherein an associated magnet exhibits a negative scale factor temperature coefficient to thereby permit a gain of said amplifier to increase.

12. The method of claim 11 further comprising the step of:
configuring said at least one resistor to comprise a fixed low temperature coefficient resistor.

13. The method of claim 12 further comprising the step of:
choosing said fixed low temperature coefficient resistor to thereby obtain a flat resultant temperature coefficient thereof.

14. A method for signal-conditioning utilizing a signal-conditioning circuit, said method comprising the step of:
applying an offset correction voltage to a noninverting input of a signal-conditioning circuit;
applying a magnetoresistor half-bridge signal to an inverting input of said signal-conditioning circuit;
compensating a voltage at said noninverting input to drive an output voltage of said signal-conditioning circuit to an input voltage divided by a value of two by calibration thereof;
configuring said signal-conditioning circuit to comprise at least one magnetoresistor in series with at least one resistor located in an inverting input of an amplifier associated with said signal-conditioning circuit;
wherein said at least one magnetoresistor exhibits a negative scale factor temperature coefficient; and
wherein an associated magnet exhibits a negative scale factor temperature coefficient to thereby permit a gain of said amplifier to increase with temperature.

15. A system for signal-conditioning utilizing a signal-conditioning circuit, said system comprising:
an offset correction voltage applied to a noninverting input of a signal-conditioning circuit;
a magnetoresistor half-bridge signal applied to an inverting input of said signal-conditioning circuit; and
a voltage compensated at said noninverting input to drive an output voltage of said signal-conditioning circuit to an input voltage divided by a value of two by calibration.

16. The system of claim 15 wherein said signal-conditioning circuit comprises an InSb signal-conditioning circuit.

17. The system of claim 15 wherein said signal-conditioning circuit comprises:
a noninverting signal input for application of offset correction voltages;
an inverting input for application of magnetoresistor half bridge signals; and
a temperature compensator.

18. The system of claim 15 wherein said magnetoresistor half-bridge signal is generated utilizing at least one equivalent magnetoresistor configured within said signal-conditioning circuit.

19. The system of claim 15 wherein said magnetoresistor half-bridge signal is generated utilizing a plurality of magnetoresistors configured within said signal-conditioning circuit.

20. The system of claim 15 wherein said signal-conditioning circuit comprises at least two magnetoresistors.

21. The system of claim 15 wherein said signal-conditioning circuit comprises a first magnetoresistor coupled to a second magnetoresistor at a first node, wherein said first magnetoresistor is coupled to a supply voltage and said second magnetoresistor is coupled to a ground.

22. The system of claim 21 wherein said signal-conditioning circuit comprises a first resistor coupled to a second resistor at a second node, wherein said first resistor is coupled to said supply voltage and said second resistor is coupled to said ground, such that said second node is coupled to a positive input of said amplifier.

23. The method of claim 22 wherein said signal-conditioning circuit comprises a third resistor coupled to said first node and to a third node, wherein said third node is connected to a negative input of said amplifier.

24. The system of claim 23 wherein said signal-conditioning circuit comprises a fourth resistor coupled to said third node and to an output of said amplifier.

25. The system of claim 15 further comprising:
said signal-conditioning circuit comprising at least one magnetoresistor in series with at least one resistor located in an inverting input of an amplifier associated with said signal-conditioning circuit;
wherein said at least one magnetoresistor comprises an InSb that exhibits a negative scale factor temperature coefficient; and
wherein an associated magnet exhibits a negative scale factor temperature coefficient to thereby permit a gain of said amplifier to increase with temperature.

26. The system of claim 25 wherein said at least one resistor comprises a fixed low temperature coefficient resistor.

27. The system of claim 26 wherein said fixed low temperature coefficient resistor is chosen to thereby obtain a flat resultant scale factor temperature coefficient thereof.

28. A system for signal-conditioning utilizing a signal-conditioning circuit, said system comprising:
an offset correction voltage applied to a noninverting input of a signal-conditioning circuit;
a magnetoresistor half-bridge signal applied to an inverting input of said signal-conditioning circuit;
a voltage compensated at said noninverting input to drive an output voltage of said signal-conditioning circuit to an input voltage divided by a value of two by calibration thereof;
said signal-conditioning circuit configured to comprise at least one magnetoresistor in series with at least one resistor located in an inverting input of an amplifier associated with said signal-conditioning circuit;
wherein said at least one magnetoresistor exhibits a negative scale factor temperature coefficient; and
wherein an associated magnet exhibits a negative scale factor temperature coefficient to thereby permit a gain of said amplifier to increase with temperature.

29. An InSb signal-conditioning circuit, comprising:
a noninverting signal input for application of offset correction voltages;
an inverting input for application of magnetoresistor half-bridge signals; and
a temperature compensator.
